(19) United States
(12) Patent Application Publication
(10) Pub. No.: US 2011/0140571 A1
(43) Pub. Date: Jun. 16, 2011

(54) PACKAGE MANUFACTURING METHOD, PIEZOELECTRIC VIBRATOR, AND OSCILLATOR

(76) Inventors: Yoshihisa Tange, Chiba-shi (JP); Yoshifumi Yoshida, Chiba-shi (JP)

(21) Appl. No.: 12/963,315

(22) Filed: Dec. 8, 2010

(30) Foreign Application Priority Data
Dec. 10, 2009 (JP) 2009-280898

(51) Int. Cl. H01L 41/00; H01L 41/22

(52) U.S. Cl. 310/311; 29/25.35

(57) ABSTRACT

There is provided a package manufacturing method capable of manufacturing high-quality and high-accuracy products without requiring complicated processes. A method for manufacturing a package including a base board and a lid board bonded to each other so as to form a cavity at an inner side and penetration electrodes that electrically connect the inside of the cavity to the outside of a base board made of a glass material includes a penetration hole forming step of forming penetration holes in a base board wafer; a rivet member insertion step of inserting conductive rivet members made of a metal material into the penetration holes; a welding step of heating the base board wafer to a temperature higher than the softening point of the glass material so as to weld the base board wafer to the rivet members; and a cooling step of cooling the base board wafer. Each of the rivet members has one end of which the sectional area is larger than the other portion, and the one end is positioned in the outside of the base board.

### RELATED APPLICATIONS

This application claims priority under 35 U.S.C. §119 to Japanese Patent Application No. 2009-280898 filed on Dec. 10, 2009, the entire content of which is hereby incorporated by reference.

### BACKGROUND OF THE INVENTION

1. Field of the Invention

The present invention relates to a package for electronic components including a plurality of boards which are bonded to each other so as to form a cavity at an inner side thereof and penetration electrodes that electrically connect the inside of the cavity to the outside of a base board among the plural boards.

2. Description of the Related Art

Recently, piezoelectric vibrators utilizing quartz crystal or the like have been used in cellular phones and portable information terminals as the time source, the timing source of a control signal or the like, a reference signal source, and the like. Although there are various piezoelectric vibrators of this type, an SMD (Surface Mount Device)-type piezoelectric vibrator is one known example thereof. As the piezoelectric vibrator of this type, a three-layered piezoelectric vibrator in which a piezoelectric board having a piezoelectric vibrating reed formed thereon is bonded to be interposed between the base board and a lid board is generally known. In this case, the piezoelectric vibrating reed is mounted on the base board and accommodated in a cavity that is formed between the base board and the lid board.

Moreover, in recent years, instead of the three-layered piezoelectric vibrator, a two-layered piezoelectric vibrator has also been developed. The piezoelectric vibrator of this type has a two-layered structure in which a base board and a lid board are directly bonded and packaged, and a piezoelectric vibrating reed is accommodated in a cavity formed between the two boards. The two-layered piezoelectric vibrator is suitably used in that it is excellent in achieving a thin profile compared with the three-layered structure.

As an example of a method for manufacturing such a packaged two-layered piezoelectric vibrator, a package manufacturing method in which a conductive member such as a silver paste is filled in penetration holes formed in a base board made of a glass material and baked so as to form penetration electrodes, and quartz crystal vibrating reeds in a cavity are electrically connected to the outer electrodes provided outside the base board is known.

However, according to this method, there is a case where since a very small gap is present between the penetration holes and the conductive member, outer air enters into the package to deteriorate the degree of vacuum of the inside of the package, and as a result, causing deterioration in the properties of the quartz crystal vibrator. As countermeasures thereof, as proposed in JP-A-2003-209198, JP-A-2002-121037, and JP-A-2002-124845, a method of preventing deterioration of the degree of vacuum by burying a rivet-attached electrode pin in each penetration hole formed in a base board and heating to a temperature equal to or higher than the softening point of the glass so as to weld the glass and the electrode pins to each other is known.

In a package manufactured by the package manufacturing method disclosed in JP-A-2003-209198, JP-A-2002-121037, and JP-A-2002-124845, a tip end of a narrow core portion of each of the electrode pins buried in the base board rather than the rivet portion thereof is exposed to the outside of the package. Therefore, there are great difficulties when frequency adjustment is performed before a cap member is overlaid so as to perform sealing. When the frequency adjustment is performed, it is necessary to perform the frequency adjustment to obtain a desired frequency while performing measurement with measurement probe pins being in contact with the penetration electrodes exposed to the outside of the package. However, there is a problem in that since the sectional area of the core portion of each of the electrode pins is very small, contact defects are caused.

In order to facilitate the frequency adjustment, forming outer electrodes on the penetration electrodes exposed to the outside of the package in advance may be considered. However, both lead-out electrodes for mounting electronic components on the base board and outer electrodes positioned outside the base board are formed on the base board which is not bonded to a lid board. Therefore, an electrode forming process is very complicated, it is very difficult to stably manufacture the base board and secure quality.

The present invention has been made in view of the above problems, and an object of the present invention is to provide a package manufacturing method capable of manufacturing high-quality and high-accuracy products without requiring complicated processes.

### SUMMARY OF THE INVENTION

The present invention provides the following means in order to solve the problems.

According to an aspect of the present invention, there is provided a method for manufacturing a package including plural boards bonded to each other so as to form a cavity at the inner side and penetration electrodes that electrically connect the inside of the cavity to the outside of a base board made of a glass material among the plural boards, the method including: a penetration hole forming step of forming penetration holes in a base board wafer; a rivet member insertion step of inserting conductive rivet members made of a metal material into the penetration holes; a welding step of heating the base board wafer to a temperature higher than the softening point of the glass material so as to weld the base board wafer to the rivet members; and a cooling step of cooling the base board wafer, wherein each of the rivet members has one end of which the sectional area is larger than the other portion, and the one end is exposed to the outside of the base board. The rivet member may have a shape such that the one end is connected to a core portion which is the other portion with a step therebetween. The one end of the rivet member may have an approximately disk shape or an approximately rectangular plate shape. Moreover, the rivet member may have a shape such that the one end is smoothly connected to the other portion and may have an approximately truncated conical shape.

According to this aspect, a member of which one end has a larger sectional area than the other portion is used as the rivet member to be used as the penetration electrode, and when the manufacturing of the base board is finished, the one end of the rivet member is exposed to the outside of the base board. Therefore, a sufficient surface area for allowing the probe pin of a measuring instrument used at the time of frequency adjustment, for example, to make contact with the one end of the rivet member having the large sectional area.

In the package manufacturing method according to the aspect of the present invention, after cooling the base board wafer, the surface of the base board wafer including a part of the one end of the rivet member is polished.

In this case, the surface of the base board wafer is polished so that a part of the one end of the rivet member remains unpolished. Therefore, it is possible to provide a high degree of flatness to the one surface of the base board wafer by polishing. At the same time, by leaving the one end of the rivet member having a large sectional area unpolished, it is possible to secure an area for allowing the probe pin of a measuring instrument used at the time of frequency adjustment to make contact with the unpolished one end of the rivet member.

According to another aspect of the present invention, there is provided a piezoelectric vibrator in which a piezoelectric vibrating reed mounted on the other end of the rivet member is accommodated in a cavity of the package manufactured by the package manufacturing method according to the above aspect of the present invention. According to a further aspect of the present invention, there is provided an oscillator including the piezoelectric vibrator according to the above aspect of the present invention and an integrated circuit to which the piezoelectric vibrator is electrically connected as an oscillating piece.

According to the above aspect of the present invention, since a sufficient area for allowing the probe pin of a measuring instrument used at the time of frequency adjustment, for example, to make contact with the rivet member serving as the penetration electrode, a complicated process of forming an outer electrode on a penetration electrode exposed to the outside of a package in advance is not necessary. Therefore, the electrode forming process becomes simple, and it is possible to stably manufacture a base board and secure and improve the quality. Moreover, it is possible to secure stable conduction between the piezoelectric vibrating reed and the outer electrode and secure stable air-tightness of the inside of the cavity of the piezoelectric vibrator. Thus, the performance of the piezoelectric vibrator can be made uniform.

### BRIEF DESCRIPTION OF THE DRAWINGS

FIG. 1 is a perspective view showing an external appearance of an example of a piezoelectric vibrator according to an embodiment of the present invention.

FIG. 2 is a sectional view of the piezoelectric vibrator shown in FIG. 1 taken along the line A-A in FIG. 3.

FIG. 3 is a sectional view of the piezoelectric vibrator shown in FIG. 1 taken along the line B-B in FIG. 2.

FIG. 4 is a perspective view showing an external appearance of an example of a rivet member used for manufacturing the piezoelectric vibrator shown in FIG. 1.

FIG. 5 is a perspective view showing an external appearance of an example of a rivet member used for manufacturing the piezoelectric vibrator shown in FIG. 1.

FIG. 6 is a perspective view showing an external appearance of an example of a rivet member used for manufacturing the piezoelectric vibrator shown in FIG. 1.

FIG. 7 is a flowchart showing the flow of the manufacturing process of the piezoelectric vibrator shown in FIG. 1.

FIG. 8 is a perspective view illustrating a penetration hole forming step in the flowchart shown in FIG. 7, showing a state where penetration holes are formed on a base board wafer serving as a base material of a base board.

FIG. 9 is a diagram illustrating the penetration hole forming step in the flowchart shown in FIG. 7, showing a penetration hole forming mold and a base board wafer.

FIG. 10 is a diagram illustrating the penetration hole forming step in the flowchart shown in FIG. 7, showing a state where a penetration hole forming mold forms depressions for forming penetration holes on the base board wafer.

FIG. 11 is a diagram illustrating the penetration hole forming step in the flowchart shown in FIG. 7, showing a state where the depressions for forming the penetration holes on the base board wafer are formed by the penetration hole forming mold.

FIG. 12 is a diagram illustrating the penetration hole forming step in the flowchart shown in FIG. 7, showing a state where the penetration holes are formed by a method such as polishing.

FIG. 13 is a diagram illustrating a rivet member insertion step in the flowchart shown in FIG. 7.

FIG. 14 is a diagram illustrating a welding step in the flowchart shown in FIG. 7, showing a state before the welding step is performed.

FIG. 15 is a diagram illustrating the welding step in the flowchart shown in FIG. 7, showing a state after the welding step is performed.

FIG. 16 is a diagram illustrating a polishing step in the flowchart shown in FIG. 7, showing a state after the polishing step is performed.

FIG. 17 is a diagram showing a state after the polishing step is performed using the modification of the rivet member shown in FIG. 6.

FIG. 18 is a diagram showing a state where the penetration electrodes are formed on the base board wafer.

FIG. 19 is a diagram showing a state where the penetration electrodes are formed on the base board wafer using the modification of the rivet member shown in FIG. 5.

FIG. 20 is a diagram showing an example of an oscillator according to an embodiment of the present invention.

### DETAILED DESCRIPTION OF PREFERRED EMBODIMENT

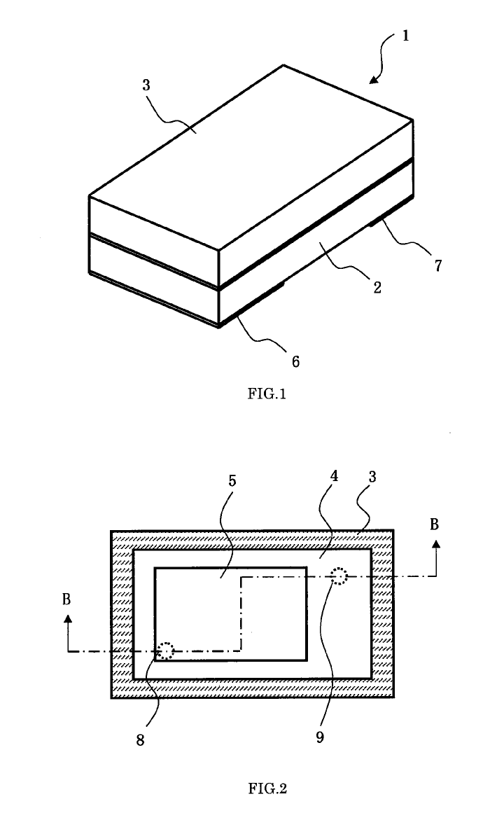

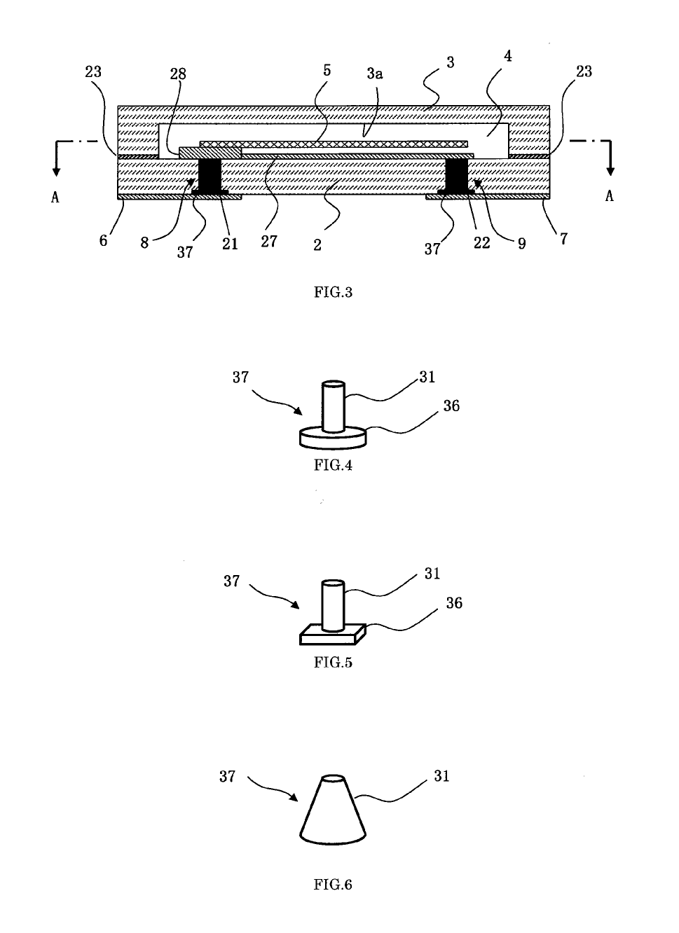

Hereinafter, a piezoelectric vibrator which is an example of a package according to an embodiment of the present invention will be described with reference to FIGS. 1 to 4.

As shown in FIGS. 1 to 3, a piezoelectric vibrator 1 according to the present embodiment is an SMD (Surface Mount Device)-type piezoelectric vibrator which is formed in the form of a box laminated in two layers of a base board 2 and a lid board 3 and in which a piezoelectric vibrating reed 5 is accommodated in a cavity 4 at an inner portion thereof. The piezoelectric vibrating reed 5 and outer electrodes 6 and 7 which are provided at an outer side of the base board 2 are electrically connected to each other by a pair of penetration electrodes 8 and 9 penetrating through the base board 2.

The base board 2 is a transparent insulating board made of a glass material, for example, soda-lime glass, and is formed in a board-like form. The base board 2 is formed with a pair of penetration holes 21 and 22 for forming the pair of penetration electrodes 8 and 9. The lid board 3 is a transparent insulating board made of glass material, for example, soda-lime glass, similarly to the base board 2, and is formed in a board-like form having a size capable of being superimposed onto the base board 2. On a bonding surface side of the lid board 3 to be bonded with the base board 2, the lid board 3 is formed with a rectangular recess portion 3a in which the piezoelectric vibrating reed 5 is accommodated. The recess portion 3a forms the cavity 4 that accommodates the piezoelectric vibrating reed 5 when the base board 2 and the lid board 3 are superimposed onto each other. The lid board 3 is anodically bonded to the base board 2 with a bonding material 23 disposed therebetween in a state where the recess portion 3a faces the base board 2.

The piezoelectric vibrating reed 5 is a rectangular AT-cut quartz crystal vibrating reed and is configured to vibrate when a predetermined voltage is applied thereto. The piezoelectric vibrating reed 5 includes a pair of excitation electrodes (not shown) which are formed on the outer surface thereof so as to produce thickness-shear vibrations, and a pair of mount electrodes (not shown) which are electrically connected to the pair of excitation electrodes. The piezoelectric vibrating reed 5 has a base portion which is bonded to the upper surface of the base board 2 by a conductive adhesive 28 (or metal bump), whereby the piezoelectric vibrating reed 5 is mounted on the base board 2.

A first excitation electrode of the piezoelectric vibrating reed 5 is electrically connected to one outer electrode 6 by one mount electrode and one penetration electrode 8. A second excitation electrode of the piezoelectric vibrating reed 5 is electrically connected to the other outer electrode 7 by the other mount electrode, a lead-out electrode 27, and the other penetration electrode 9. The outer electrodes 6 and 7 are provided at both ends in the longitudinal direction of the bottom surface of the base board 2. The outer electrodes may be formed at the four corners of the bottom surface of the base board 2, and two of them may be used as dummy outer electrodes.

The penetration electrodes 8 and 9 are formed by arranging rivet members 37 made of conductive metal material in the penetration holes 21 and 22, and stable electrical conduction is secured by the rivet members 37. One penetration electrode 8 is positioned above one outer electrode 6 and near the bottom of the base portion of the piezoelectric vibrating reed 5. The other penetration electrode 9 is positioned above the other outer electrode 7 and near the bottom of the tip end of the piezoelectric vibrating reed 5.

As shown in FIG. 4, the rivet member 37 has a shape such that an approximately cylindrical core portion 31 having a small diameter and a small sectional area and an approximately disk-shaped base portion 36 having a large diameter and a large sectional area are connected to be approximately coaxial to each other with a step therebetween. The rivet member 37 has the base portion 36 thereof being exposed to the bottom surface of the base board 2. That is, the rivet member 37 has the base portion 36 which is one end having a large sectional area, and which is exposed to the bottom surface of the base board 2. The rivet member 37 is fixed to the base board 2 made of glass material by welding, and the core portion 31 and the base portion 36 completely close the penetration hole 21 or 22, thus maintaining the air-tightness of the inside of the cavity 4. The rivet member 37 is formed of a conductive metal material, for example, kovar and Fe—Ni alloys (42 alloy), whose thermal expansion coefficient is close to (preferably, equal to or lower than) that of the glass material of the base board 2.

### Package Manufacturing Method

Next, a method for manufacturing a package (piezoelectric vibrator) accommodating the piezoelectric vibrating reed will be described with reference to FIGS. 7 to 16 and FIG. 18.

First, a step of manufacturing a base board wafer 41 later serving as the base board 2 is performed (S10). First, the base board wafer 41 as shown in FIG. 8 is formed. Specifically, a soda-lime glass is polished to a predetermined thickness and cleaned, and then, the affected uppermost layer is removed by etching or the like (S11). Only a part of the base board wafer 41 is shown in FIG. 8, and actually, the base board wafer 41 has a disk-like shape. The dotted line M shown in FIG. 8 is a cutting line along which the base board wafer 41 is cut in a cutting step described later. The penetration holes 21 and 22 in FIG. 8 are formed in a step, described later, of forming the penetration electrodes 8 and 9 on the base board wafer 41. Subsequently, a penetration electrode forming step of forming the penetration electrodes 8 and 9 on the base board wafer 41 is performed (S10A).

### Penetration Hole Forming Step

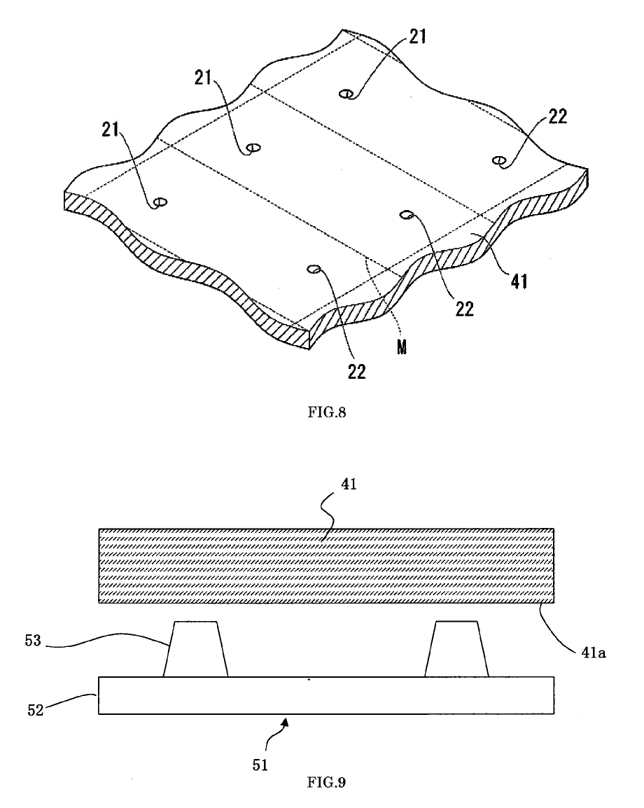

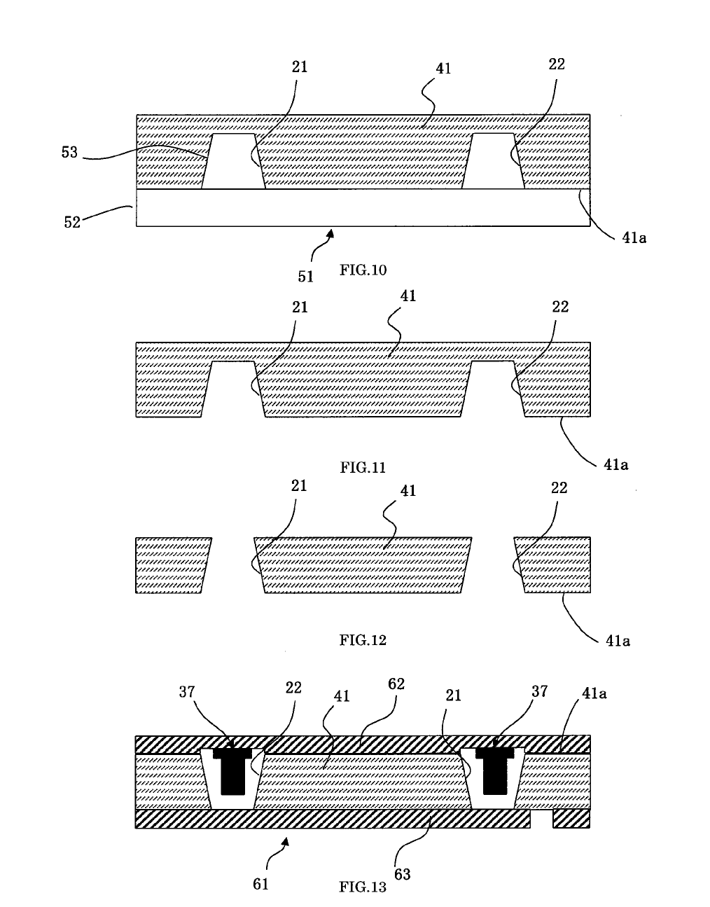

First, the penetration holes 21 and 22 penetrating through the base board wafer 41 are formed (S12). The forming of the penetration holes 21 and 22 is performed by heating the base board wafer 41 while pressing the base board wafer 41 with a penetration hole forming mold 51 made of a carbon material and having a planar portion 52 and convex portions 53 formed on one surface of the planar portion 52 as shown in FIGS. 9 and 10. After that, the base board wafer 41 on which the shapes of the convex portions 53 as shown in FIG. 11 are transferred so as to form depressions thereon is polished to a state shown in FIG. 12. In this way, the penetration holes 21 and 22 are formed on the base board wafer 41.

The planar portion 52 of the penetration hole forming mold 51 is a flat member which makes contact with one surface 41a of the base board wafer 41 when pressing the base board wafer 41. The one surface 41a of the base board wafer 41 serves as the bottom surface of the base board 2. The convex portions 53 of the penetration hole forming mold 51 is a member which transfers the shapes of the convex portions 53 to the base board wafer 41 to form depressions serving as the penetration holes 21 and 22 when pressing the base board wafer 41. The convex portions 53 have a tapered side surface for mold removal on the side surface thereof, and the approximately truncated conical shapes of the convex portions 53 are transferred to the penetration holes 21 and 22. The base board wafer 41 is welded to the rivet members 37 in a later manufacturing step, whereby the penetration holes 21 and 22 are closed by the rivet members 37.

In the penetration hole forming step, first, as shown in FIG. 9, the penetration hole forming mold 51 is placed with the convex portions 53 positioned on the upper side, and the base board wafer 41 is placed thereon. This assembly is placed in a heating furnace with pressure applied in a high temperature state of about 900° C., and as shown in FIGS. 10 and 11, the shapes of the convex portions 53 are transferred to the base board wafer 41 to form depressions. After that, as shown in FIG. 12, the other surface of the base board wafer 41 where no depression is formed is polished, whereby the penetration holes 21 and 22 having an approximately truncated conical shape are formed on the base board wafer 41. The convex portions 53 of the penetration hole forming mold 51 may penetrate through the base board wafer 41 when heating the base board wafer 41, and in this way, the polishing step may be omitted.

At that time, since the planar portion 52 and the convex portions 53 are made of a carbon material, the base board wafer 41 heated and softened does not adhere onto the planar portion 52 and the convex portions 53. Therefore, the penetration hole forming mold 51 can be easily removed from the base board wafer 41. Moreover, since the planar portion 52 and the convex portions 53 are made of a carbon material, it is possible to prevent the base board wafer 41 in the high temperature state from absorbing gas generated therefrom and forming pores in the base board wafer 41, thus decreasing porosity of the base board wafer 41. In this way, it is possible to secure air-tightness of the cavity 4.

Subsequently, the base board wafer 41 is cooled gradually while decreasing the temperature. This cooling method will be described in detail when describing a cooling step performed after the welding step.

### Rivet Member Insertion Step

Subsequently, a step of inserting the rivet members 37 into the penetration holes 21 and 22 is performed (S13). As shown in FIG. 13, the base board wafer 41 is placed on a pressurizing mold 63 of a welding mold 61 described later, and the rivet members 37 are inserted, from the above, into the penetration holes 21 and 22. In this state, the pressurizing mold 63 and a receiving mold 62, described later, of the welding mold 61 pinch the base board wafer 41 and the rivet members 37 therebetween, and this assembly is turned upside down as shown in FIG. 14. The step of inserting the rivet members 37 into the penetration holes 21 and 22 is performed using an inserting machine. At this time, in top view, the base portions 36 have a shape such that they are larger than the openings of the penetration holes 21 and 22. Since the rivet members 37 have the base portions 36, they can be easily inserted into the penetration holes 21 and 22, and workability is improved. Moreover, as shown in FIG. 14, the tip end of the core portion 31 of each of the rivet members 37 does not protrude from the other surface 41b of the base board wafer 41, a gap is formed between the tip end of the core portion 31 and a pressurization mold planar portion 67 of the pressurizing mold 63.

### Welding Step

Subsequently, a step of heating the base board wafer 41 so that the base board wafer 41 is welded to the rivet members 37 is performed (S14). As shown in FIG. 14, the welding step is performed by placing the base board wafers 41 one by one in the welding mold 61 made of a carbon material and having the receiving mold 62 disposed on the lower side of the base board wafer 41 and the pressurizing mold 63 disposed on the upper side of the base board wafer 41 and heating the base board wafer 41 while pressing the base board wafer 41.

The receiving mold 62 is a mold that holds the lower side of the base board wafer 41 and the rivet members 37. The receiving mold 62 has a shape such that it is larger than the base board wafer 41 in top view and it extends along the lower side of the base board wafer 41 in which the rivet members 37 are inserted into the penetration holes 21 and 22, and a part of each of the base portions 36 protrudes from the surface 41a of the base board wafer 41. The receiving mold 62 includes a receiving mold planar portion 65 that makes contact with the surface 41a of the base board wafer 41 when holding the base board wafer 41 and receiving mold recess portions 66 which make contact with the base portions 36 and are recess portions corresponding to the base portions 36. The receiving mold recess portions 66 are formed in alignment with the positions of the base portions 36 of the rivet members 37 provided in the penetration holes 21 and 22 of the base board wafer 41. The base portions 36 are fitted in the receiving mold recess portions 66, whereby the receiving mold 62 is able to hold the rivet members 37, and the rivet members 37 are prevented from being removed, and the core portions 31 are prevented from being displaced.

The pressurizing mold 63 is a mold that presses the upper side of the base board wafer 41 and has the same top-view shape as the receiving mold 62. The pressurizing mold 63 includes the pressurizing mold planar portion 67 that makes contact with the other surface 41b of the base board wafer 41. The pressurizing mold planar portion 67 is a flat member that makes contact with the other surface 41b of the base board wafer 41. The pressurizing mold 63 includes a slit 70 which is provided at an end thereof so as to penetrate through the pressurizing mold 63. The slit 70 can be used as an escape hole for air and surplus glass material of the base board wafer 41 when the base board wafer 41 is heated and pressed.

In the welding step, first, the base board wafer 41 and the rivet members 37 set on the welding mold 61 are placed on a mesh belt made of metal, and in such a state, they are inserted in a heating furnace and heated. Moreover, using a press machine or the like disposed in the heating furnace, the base board wafer 41 is pressed by the pressurizing mold 63 at a pressure of 30 to 50 g/cm², for example. The heating temperature is set to a temperature (for example, about 900° C.) higher than the softening point (for example, 545° C.) of the glass material of the base board wafer 41.

The heating temperature is increased gradually, and the temperature increase stops temporarily at a time when the heating temperature reaches a temperature (for example, 550° C.) that is about 5° C. higher than the softening point of the glass material, and then the temperature increase goes on to about 900° C. In this way, by temporarily stopping the temperature increase at a temperature about 5° C. higher than the softening point of the glass material and maintaining the temperature, the softening of the base board wafer 41 can be made uniform.

Since the base board wafer 41 is pressed in a high temperature state, the base board wafer 41 is welded to the rivet members 37, so that the rivet members 37 close the penetration holes 21 and 22. By forming another convex or recess portion on the welding mold 61, a recess or convex portion may be formed on the base board wafer 41 when the base board wafer 41 is welded to the rivet members 37.

### Cooling Step

Subsequently, the base board wafer 41 is cooled (S15). The cooling of the base board wafer 41 is performed by gradually decreasing the temperature from about 900° C. which is the heating temperature during the welding step. The rate of cooling is set such that the rate of cooling from about 900° C. to a temperature 50° C. higher than the strain point of the glass material that forms the base board wafer 41 is faster than the rate of cooling from a temperature 50° C. higher than the strain point to a temperature 50° C. lower than the strain point. Particularly, the cooling from the slow cooling point of the glass material that forms the base board wafer 41 to the strain point is performed slowly. When cooling from a temperature 50° C. higher than the strain point to a temperature 50° C. lower than the strain point, the base board wafer 41 is moved to another furnace, for example.

In this way, by slowly performing the cooling between the temperatures within 50° C. of the strain point, it is possible to suppress the occurrence of strains in the base board wafer 41. Moreover, since the thermal expansion coefficients of the glass material of the base board wafer 41 and the metal material of the rivet members 37 are different, if strains are formed in the base board wafer 41, a gap may be formed between the penetration holes 21 and 22 and the rivet members 37, and cracks may be formed near the rivet members 37. By preventing strains in the base board wafer 41, it is possible to realize a state where the base board wafer 41 is reliably welded to the rivet members 37.

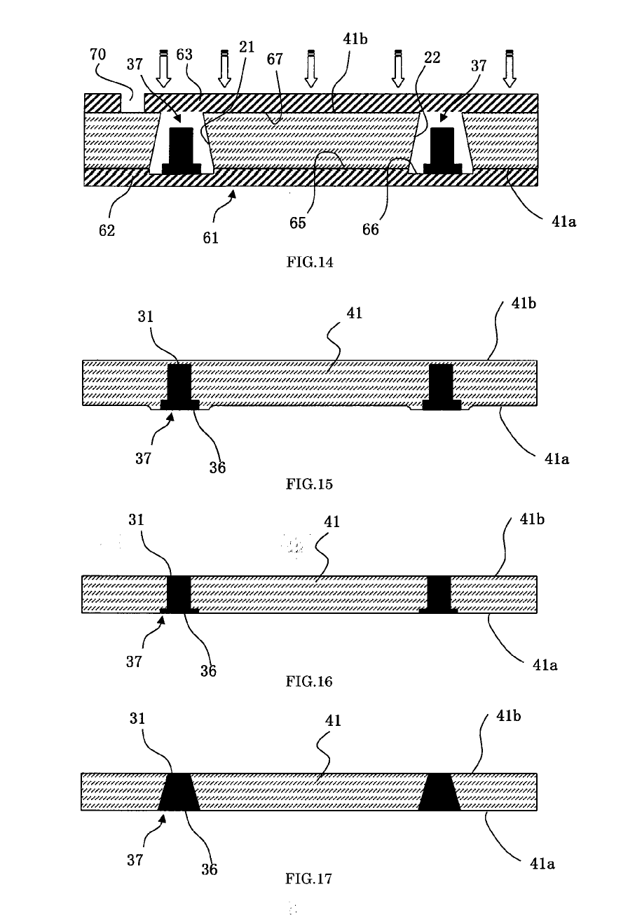

The cooling time may be reduced by setting the rate of cooling from a temperature 50° C. lower than the strain point to the room temperature so as to be faster than the rate of cooling from a temperature 50° C. higher than the strain point to a temperature 50° C. lower than the strain point. In this way, the base board wafer 41 is formed as shown in FIG. 15 in which the core portions 31 of the rivet members 37 close the penetration holes 21 and 22. Here, in the state before the welding step is performed, since a gap is formed between the tip end of each of the core portions 31 of the rivet members 37 and the pressurizing mold planar portion 67 of the pressurizing mold 63, a glass material is filled into the gap. Therefore, the core portions 31 of the rivet members 37 are not exposed to the other surface 41b of the base board wafer 41, and the other surface 41b of the base board wafer 41 becomes flat because the shape of the pressurizing mold planar portion 67 is transferred thereto. In the penetration hole forming step, the cooling of the heated base board wafer 41 is performed in accordance with the above-described cooling method.

### Polishing Step

Subsequently, the surfaces 41a and 41b of the base board wafer 41 are polished from both sides so that a part of each of the base portions 36 of the rivet members 37 and a part of each of the core portions 31 are polished (S16). At this time, since the other surface 41b of the base board wafer 41 is flat, it is possible to start polishing the one surface 41a of the base board wafer 41 using the other surface 41b as a reference surface of the polishing. Thus, polishing can be realized with a very high degree of flatness. Polishing of the base portions 36 and the core portions 31 of the rivet members 37 is performed in accordance with the known method. As shown in FIG. 16, the surfaces 41a and 41b of the base board wafer 41 and the exposed surfaces of the penetration electrodes 8 and 9 (the rivet members 37) are substantially even with each other. At that time, rather than polishing the entirety of the base portions 36, polishing is performed so that a part (for example, half or the like) of each of the base portions 36 remains unpolished. In this way, the penetration electrodes 8 and 9 are formed in the base board wafer 41.

Subsequently, a bonding film forming step (S17) where a conductive material is patterned on the surface 41a of the base board wafer 41 to form a bonding film and a lead-out electrode forming step (S18) are performed. In this way, the step of manufacturing the base board wafer 41 ends.

Regarding frequency adjustment, after the piezoelectric vibrating reed 5 is disposed in the base board wafer 41 so as to be mounted on the penetration electrodes 8 and 9, frequency is adjusted to a desired frequency. FIG. 18 is a diagram showing the base board wafer 41 as seen from the surface 41a. As shown in FIG. 18, the base portions 36 of the rivet members 37 are exposed to the surface 41a of the base board wafer 41 serving as the bottom surface of the base board 2. Then, the probe pins of a measuring instrument called a network analyzer for performing frequency adjustment are brought into contact with the base portions 36. Frequency adjustment is performed while measuring the frequency of the piezoelectric vibrating reed 5 with the measuring instrument through the probe pins.

Subsequently, at the same or a different time as the manufacturing of the base board 2, a lid board wafer later serving as the lid board 3 is manufactured (S30). In the step of manufacturing the lid board 3, first, a disk-shaped lid board wafer later serving as the lid board 3 is formed. Specifically, a soda-lime glass is polished to a predetermined thickness and cleaned, and then, the affected upper-most layer is removed by etching or the like (S31). Subsequently, the recess portion 3a to be used as the cavity 4 is formed in the lid board wafer by etching, press working, or the like (S32). After that, the surface of the lid board wafer is polished (S33).

The piezoelectric vibrating reed 5 is disposed in the cavity 4 formed between the base board wafer 41 and the lid board wafer formed in this way so as to be mounted on the penetration electrodes 8 and 9, and the base board wafer 41 and the lid board wafer are anodically bonded to each other. Then, a pair of the outer electrodes 6 and 7 are formed so as to be electrically connected to a pair of the penetration electrodes 8 and 9, and the frequency of the piezoelectric vibrator 1 is finely adjusted. Moreover, a cutting step where the wafer assembly is cut in small fragments is performed, and an inner electrical property test is conducted, whereby a package (piezoelectric vibrator 1) in which the piezoelectric vibrating reed 5 is accommodated is formed.

In the package manufacturing method according to the present embodiment, in the step of forming the penetration electrodes 8 and 9 in the base board wafer 41, the base board wafer 41 in which the rivet members 37 are inserted into the penetration holes 21 and 22 is held by the receiving mold 62, and the base board wafer 41 is heated to a temperature higher than the softening point of the glass material and pressed by the pressurizing mold 63. In this way, the base board wafer 41 is welded to the core portions 31, and the penetration electrodes 8 and 9 are formed. In the polishing step, rather than polishing the entirety of the base portions 36 of the penetration electrodes 8 and 9, each of the base portions 36 of which the sectional area is larger than the core portions 31 remains unpolished so as to be exposed to the surface 41a of the base board wafer 41. For this reason, it is possible to secure a sufficient area for making contact with the probe pins of the measuring instrument in the frequency adjustment step, and the contacting operation can be performed very easily. Thus, the measurement can be performed stably, and stable quality can be provided.

### Modifications

Next, modifications of the above-described embodiment will be described with reference to FIGS. 5, 6, 17, and 19. The same members and portions as those of the above-described embodiment will be denoted by the same reference numerals and description thereof will be omitted, and only different configurations will be described.

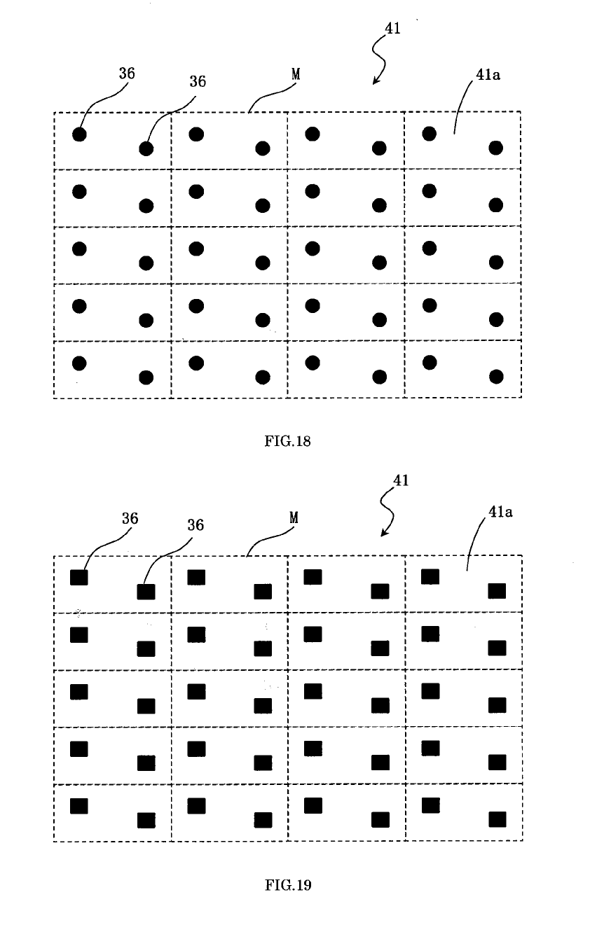

A rivet member 37 shown in FIG. 5 has the base portion 36 having an approximately rectangular plate shape in place of the approximately disk-shaped base portion 36 shown in FIG. 4. The rivet member 37 shown in FIG. 5 also has the base portion 36 which is one end having a large sectional area, and which is exposed to the bottom surface of the base board 2. FIG. 19 is a diagram showing the base board wafer 41 as seen from the surface 41a when the rivet member 37 shown in FIG. 5 is used. In the case of the rivet member 37 shown in FIG. 5, similarly to the above-described embodiment, since the base portion 36 remains unpolished, the base portion 36 having a sectional area larger than the core portion 31 is exposed to the bottom surface of the base board wafer. For this reason, it is possible to secure a sufficient area for making contact with the probe pins of the measuring instrument in the frequency adjustment step, and the contacting operation can be performed very easily. Thus, the measurement can be stably performed, and a stable quality can be provided.

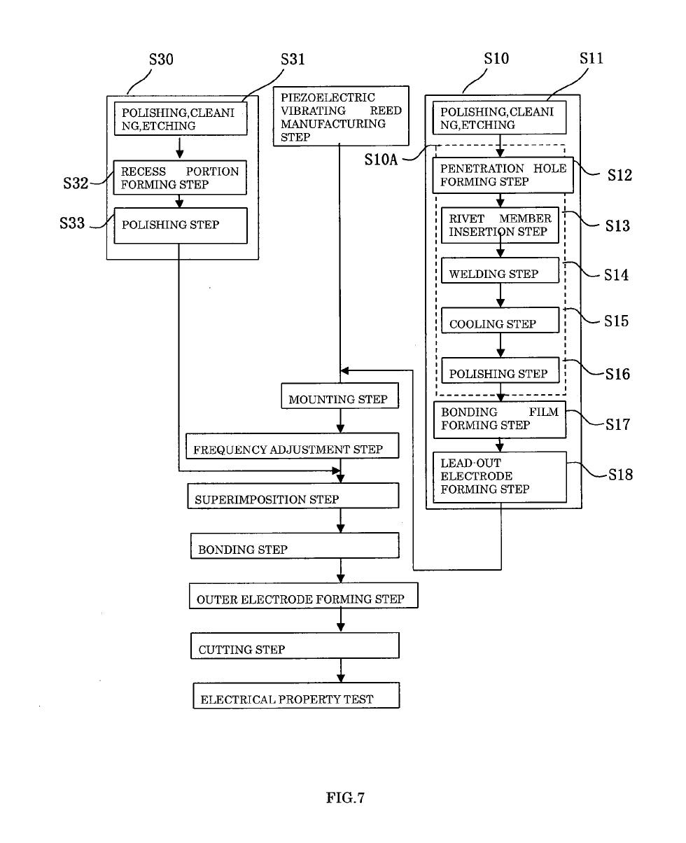

A rivet member 37 shown in FIG. 6 is formed by only a core portion 31 having an approximately truncated conical shape unlike the rivet members 37 shown in FIGS. 4 and 5 which each have a shape such that the base portion 36 and the core portion 31 are connected with a step therebetween. The rivet member 37 shown in FIG. 6 also has one end having a large sectional area which is exposed to the bottom surface of the base board 2. FIG. 17 is a diagram showing the state of the base board wafer 41 after the polishing step when the rivet member 37 shown in FIG. 6 is used. In the case of the rivet member 37 shown in FIG. 6, the portion of the core portion 31 having a larger sectional area is exposed to the bottom surface of the base board wafer. For this reason, it is possible to secure a sufficient area for making contact with the probe pins of the measuring instrument in the frequency adjustment step, and the contacting operation can be performed very easily. Thus, the measurement can be performed stably, and stable quality can be provided. Particularly, the rivet member 37 shown in FIG. 6 has an approximately truncated conical shape in which the base portion 36 is not present. For this reason, unlike the rivet members 37 shown in FIGS. 4 and 5, it is not necessary to carefully control the amount of polishing at the time of polishing the base portion 36, and the polishing step becomes simple.

### Oscillator

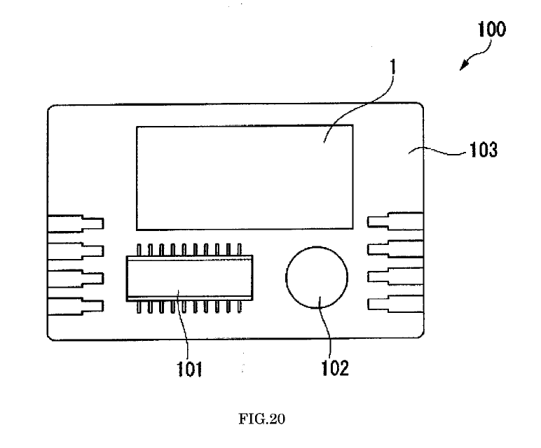

Next, an embodiment of the oscillator according to the present invention will be described with reference to FIG. 20. As shown in FIG. 20, an oscillator 100 of the present embodiment is one in which the piezoelectric vibrator 1 is configured as an oscillating piece that is electrically connected to an integrated circuit 101. The oscillator 100 includes a board 103 on which an electronic component 102 such as a capacitor is mounted. The integrated circuit 101 for the oscillator is mounted on the board 103, and the piezoelectric vibrator 1 is mounted in the vicinity of the integrated circuit 101. The electronic component 102, integrated circuit 101, and piezoelectric vibrator 1 are electrically connected by a wiring pattern which is not shown. It should be noted that these components are molded by resin which is not shown.

In the oscillator 100 configured in this manner, the piezoelectric vibrating reed 5 in the piezoelectric vibrator 1 vibrates when a voltage is applied to the piezoelectric vibrator 1. This vibration is converted to an electrical signal by the piezoelectric characteristics of the piezoelectric vibrating reed 5 and is then input to the integrated circuit 101 as the electrical signal. The input electrical signal is subjected to various kinds of processing by the integrated circuit 101 and is then output as a frequency signal. In this way, the piezoelectric vibrator 1 functions as an oscillating piece. By selectively setting the configuration of the integrated circuit 101, for example, an RTC (Real Time Clock) module, according to the demands, it is possible to add a function of controlling the date or time for operating the device or an external device or providing the time or calendar other than a single-function oscillator for a timepiece.

According to the oscillator 100 of the present embodiment, the oscillator 100 includes the high-quality piezoelectric vibrator 1 in which the air-tightness of the inside of the cavity 4 is reliable, stable conduction between the piezoelectric vibrating reed 5 and the outer electrodes 6 and 7 is secured, and operation reliability is improved. Therefore, stable conduction can be secured in the oscillator 100 itself, and it is possible to improve operation reliability to achieve high quality. In addition to this, it is possible to obtain a highly accurate frequency signal which is stable over a long period of time.

The embodiment of the package manufacturing method according to the present invention has been described hereinabove. However, the technical scope of the present invention is not limited to the embodiments above, and the present invention can be modified in various ways without departing from the spirit of the present invention. For example, in the above-described embodiment, the penetration holes 21 and 22 were formed by pressing the penetration hole forming mold 51 onto the base board wafer 41 and heating the base board wafer 41. Besides this, the penetration holes 21 and 22 may be formed in the base board wafer 41 by a sand blast method or the like. Moreover, the shape of the rivet member 37 is not particularly limited as long as the sectional area of the side of the rivet member exposed to the surface 41a of the base board wafer 41 (the bottom surface of the base board 2) is larger than the other side. Furthermore, it is not always necessary to polish the one surface 41a of the base board wafer 41. What matters is that it is necessary to obtain desired functions of the present invention.

What is claimed is:

1. A method for producing piezoelectric vibrators, comprising:
(a) defining a plurality of first substrates on a first wafer and a plurality of second substrates on a second wafer;
(b) forming a pair of through-holes in a respective at least some of the first substrates on the first wafer;
(c) placing a conductive rivet in a respective at least some of the through-holes, wherein the rivet has an upper surface and a lower surface which is made larger in area than the upper surface;
(d) hermetically closing the at least some of the through-holes under heat and pressure, leaving at least some of the rivets secured in the first wafer;
(e) hermetically bonding the first and second wafers such that at least some of the first substrates substantially coincide respectively with at least some of the corresponding second substrates, wherein a piezoelectric vibrating strip is secured in a respective pairs of at least some of coinciding first and second substrates; and
(f) cutting off respective at least some of the hermetically bonded pairs of first and second substrates from the first and second wafers.

2. The method according to claim 1, wherein forming a pair of through-holes in a respective at least some of the first substrates comprises pressing a die with a plurality projections onto the first wafer to form holes or through-holes in the first ware.

3. The method according to claim 2, wherein forming a pair of through-holes in a respective at least some of the first substrates further comprises grinding one surface of the first wafer to expose the holes through the one surface of the first wafer.

4. The method according to claim 1, wherein placing a conductive rivet in a respective at least some of the through-holes comprises placing the first wafer between dies having the rivets arranged in conformity with an arrangement of the at least some of the through-holes.

5. The method according to claim 4, wherein hermetically closing the at least some of the through-holes comprising pressing the first wafer between the dies at a temperature higher than a softening temperature of the first wafer.

6. The method according to claim 5, wherein pressing the first wafer between the dies comprises pressing the first wafer under a pressure of 30-50 g/cm² at a temperature of about 900° C.

7. The method according to claim 1, further comprising a cooling the first wafer after step (d) and before step (e), wherein a first cooling rate adopted to cool the first wafer from a heating temperature of step (d) to about a strain point of the first wafer plus 50° C. is faster than a second cooling rate adopted to cool the first wafer from the strain point of the first wafer plus 50° C. to the strain point of the first wafer minus 50° C., and a third cooling rate adopted to cool the first wafer from the strain point of the first wafer minus 50° C. to a room temperature is faster than the second cooling rate.

8. The method according to claim 1, further comprising grinding at least one surface of the first wafer after step (d) and before step (e) to expose the upper and lower surfaces from the surfaces of the first wafer.

9. The method according to claim 8, wherein grinding at least one surface of the first wafer comprises grinding at least one surface of the first wafer, along with at least one of the upper and lower surfaces of the rivet.

10. The method according to claim 1, wherein the rivet has a pillar attached to one of a circular base plate and a polygonal base plate.

11. The method according to claim 1, wherein the rivet is conical in shape.

12. A piezoelectric vibrator comprising:
a hermetically closed casing comprising first and second substrates with a cavity inside;
conductive rivets embedded in the first substrate and secured therein solely by the first substrate firmly surrounding the rivets, wherein the rivets each have an upper surface exposed inside the cavity and a lower surface larger in area than the upper surface and exposed from the first substrate; and
a piezoelectric vibrating strip secured inside the cavity and electrically connected via a conductive pattern to the upper surface of the rivets.

13. An oscillator comprising the piezoelectric vibrator defined in claim 12.
